(19) United States
(12) Patent Application Publication
(10) Pub. No.: US 2011/0291256 A1
(43) Pub. Date: Dec. 1, 2011

(54) Method for Fabricating a Semiconductor Chip Package and Semiconductor Chip Package

(76) Inventors: Rainer Steiner, Regensburg (DE); Jens Pohl, Bernhardswald (DE); Werner Robl, Regensburg (DE); Gottfried Beer, Nittendorf (DE)

(21) Appl. No.: 12/791,443

(22) Filed: Jun. 1, 2010

(51) Int. Cl. H01L 23/48; H01L 21/50

(52) U.S. Cl. 257/690; 438/125; 257/E21.499; 257/E23.01

(57) ABSTRACT

A semiconductor chip includes a contact pad on a main surface of the chip. An electrically conductive layer is applied onto the contact pad. The main surface of the semiconductor chip is covered with an insulating layer. An electrically conductive contact area is formed within the insulating layer such that the contact area and the insulating layer include coplanar exposed surfaces and the contact area is electrically connected with the electrically conductive layer and includes an extension which is greater than the extension of the electrically conductive layer along a direction parallel to the main surface of the semiconductor chip.

### TECHNICAL FIELD

The present invention relates to a method for fabricating a semiconductor chip package and a semiconductor chip package.

### BACKGROUND

Semiconductor chips include contact pads or contact elements on one or more of their outer surfaces. When fabricating a semiconductor device, in particular when housing the semiconductor chip in a semiconductor chip package, the contact pads of the semiconductor chip have to be connected to external contact elements of the semiconductor chip package.

### BRIEF DESCRIPTION OF THE DRAWINGS

Aspects of the invention are made more evident in the following detailed description of embodiments when read in conjunction with the attached drawing figures, wherein:

FIG. 1 shows a flow diagram of a method for fabricating a semiconductor chip package according to an embodiment;

FIGS. 2A-2D show schematic cross-sectional representations for illustrating an embodiment of a method for fabricating a semiconductor chip package;

FIG. 3 shows a flow diagram of a method for fabricating a semiconductor chip package according to an embodiment;

FIGS. 4A-4E show schematic cross-sectional representations for illustrating an embodiment of a method for fabricating a semiconductor chip package;

FIGS. 5A-5B show schematic top view representations of a semiconductor chip in a total view (FIG. 5A) and a partial enlarged view (FIG. 5B);

FIGS. 6A-6B show top view representations of the semiconductor chip of FIGS. 5A-5B in a total view (FIG. 6A) and a partial enlarged view (FIG. 6B);

FIGS. 7A-7B show top view representations of the semiconductor chip of FIGS. 6A-6B in a top view (FIG. 7A) and a partial enlarged view (FIG. 7B); and

FIG. 8 shows a schematic cross-sectional side view representation of a semiconductor chip package according to an embodiment.

### DETAILED DESCRIPTION OF ILLUSTRATIVE EMBODIMENTS

The aspects and embodiments are now described with reference to the drawings, wherein like reference numerals are generally utilized to refer to like elements throughout. In the following description, for purposes of explanation, numerous specific details are set forth in order to provide a thorough understanding of one or more aspects of the embodiments. It may be evident, however, to one skilled in the art that one or more aspects of the embodiments may be practiced with a lesser degree of the specific details. In other instances, known structures and elements are shown in schematic form in order to facilitate describing one or more aspects of the embodiments. It is to be understood that other embodiments may be utilized and structural or logical changes may be made without departing from the scope of the present invention. It should be noted further that the drawings are not to scale or not necessarily to scale.

In addition, while a particular feature or aspect of an embodiment may be disclosed with respect to only one of several implementations, such a feature or aspect may be combined with one or more other features or aspects of the other implementations as may be desired and advantageous for any given or particular application. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives may be used. It should be understood that these terms may be used to indicate that two elements co-operate or interact with each other regardless of whether they are in direct physical or electrical contact, or they are not in direct contact with each other. Also, the term “exemplary” is merely meant as an example, rather than the best or optimal. The following detailed description, therefore, is not to be taken in a limiting sense, and the scope of the present invention is defined by the appended claims.

The embodiments for a method of fabricating a semiconductor device and the embodiments of a semiconductor device may use various types of semiconductor chips or semiconductor substrates, among them logic integrated circuits, analog integrated circuits, mixed signal integrated circuits, sensor circuits, MEMS (Micro-Electro-Mechanical Systems), power integrated circuits, chips with integrated passives, discrete passives and so on. In general the term “semiconductor chip” as used in this application can have different meanings one of which is a semiconductor die or semiconductor substrate comprising an electrical circuit.

In several embodiments layers or layer stacks are applied to one another or materials are applied or deposited onto layers. It should be appreciated that any such terms as “applied” or “deposited” are meant to cover literally all kinds and techniques of applying layer onto each other. In particular, they are meant to cover techniques in which layers are applied at once as a whole, like, for example, laminating techniques, as well as techniques in which layers are deposited in a sequential manner, like, for example, sputtering, plating, molding, chemical vapor deposition (CVD) and so on.

The semiconductor chips may comprise contact elements or contact pads on one or more of their outer surfaces wherein the contact elements serve for electrically contacting the semiconductor chips. The contact elements may be made from any electrically conducting material, e.g., from a metal such as aluminum, gold, or copper, for example, or a metal alloy, or an electrically conducting organic material, or an electrically conducting semiconductor material.

The semiconductor chips may become covered with an insulating material. The insulating material can be any electrically insulating material like, for example, any kind of dielectric material, any kind of epoxy material, or any kind of resin or molding material. In the process of covering the semiconductor chips or dies with the insulating material, fan-out embedded dies can be fabricated. The fan-out embedded dies can be arranged in an array having the form, e.g., of a wafer and will thus be called a “re-configured wafer” further below. However, it should be appreciated that the fan-out embedded die array is not limited to the form and shape of a wafer but can have any size and shape and any suitable array of semiconductor chips embedded therein.

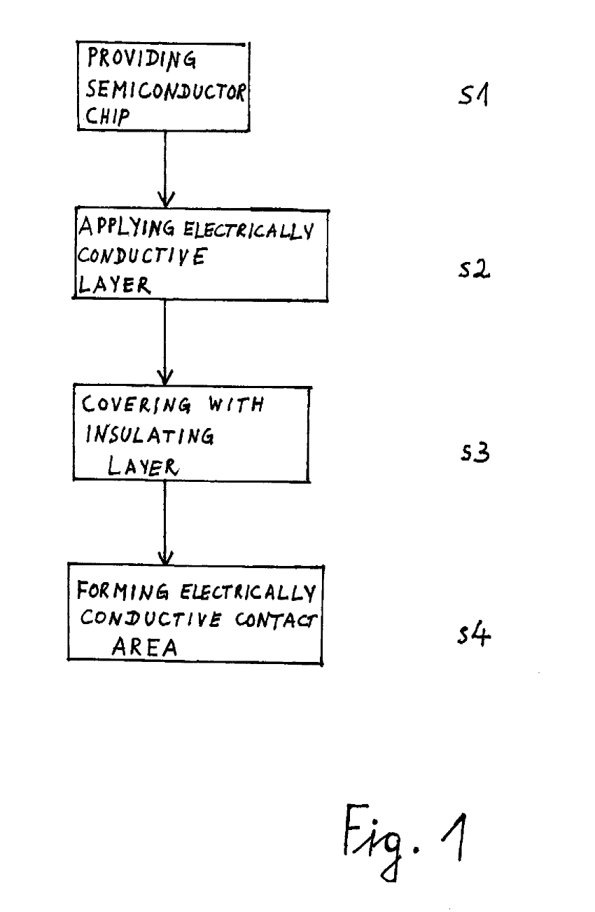

Referring to FIG. 1, there is shown a flow diagram of a method for fabricating a semiconductor chip package according to an embodiment. The method comprises providing a semiconductor chip comprising a contact pad on a main surface of the chip (s1), applying an electrically conductive layer onto the contact pad (s2), covering the main surface of the semi-conductor chip with an insulating layer (s3), and forming an electrically conductive contact area within the insulating layer such that the contact area and the insulating layer comprise coplanar exposed surfaces, and the contact area is electrically connected with the electrically conductive layer and comprises an extension which is greater than the extension of the electrically conductive layer along a direction parallel to the main surface of the semiconductor chip (s4).

The insulating layer and the electrically conductive contact area formed within the insulating layer form parts of a redistribution layer. The electrically conductive layer applied onto the contact pad forms a post on the contact pad which can, for example, be fabricated of copper. The method according to FIG. 1 thus utilizes a process where the redistribution layer is defined by embedding so-called “damascene” structures in the insulating layer in combination with the posts formed on the contact pad. The insulating layer can, for example, be formed of a dielectric layer.

According to an embodiment of the method of FIG. 1, covering with an insulating layer is performed such that the insulating layer comprises a plane or planarized upper surface after the covering step. This can be achieved either by using an appropriate material of the insulating layer which has sufficient plastic or formative properties so that the electrically conductive layer (post) being pressed into the insulating layer from below will not stand out to a considerable extent at the upper surface of the insulating layer. Alternatively or in addition to that a planarizing process like chemical-mechanical polishing (CMP), for example, can be carried out after the application of the insulating layer. As a result, the overall height of the contact pad and the electrically conductive layer applied onto the contact pad can be adjusted to any desired value and it can, for example, be half of the height or thickness of the insulating layer or even more than that. This turns out to be advantageous as the amount of material of the insulating layer to be removed thereafter to form the electrically conductive contact areas above the contact pad and the electrically conductive layer can be reduced significantly and in an adjustable manner.

The material of the insulating layer, in particular the dielectric material, can be applied onto the semiconductor chip or onto a panel comprising a plurality of semiconductor chips by methods like spin-on, spray code, roller code, lamination or other methods. During the process of applying the insulating layer, the posts on the chip contact pads are embedded in the dielectric material of the insulating layer. Thereafter the dielectric material of the insulating layer may be cured.

According to an embodiment of the method of FIG. 1, the method further comprises removing a portion of the insulating layer to form a recessed area intended to become the contact area. According to an embodiment thereof removing may comprise laser-ablating which is also called laser direct structuring (LDS). The laser-ablating or laser direct structuring process generates a damascene structure in the insulating layer. The depth of the damascene structure is preferably such that the upper surface of the electrically conductive layer or post is exposed for to allow the application of the electrically conductive contact area thereon in a later step. The material of the insulating layer can, for example, comprise a transparent material in order to allow the implementation of a pattern recognition system (PR system). Such a system allows positioning of the electrically conductive contact area of the redistribution layer in a position aligned relative to the electrically conductive layer or post by recognizing the location of the post by the pattern recognition system.

According to an embodiment of the method of FIG. 1, the recessed area in the insulating layer is filled with an electrically conductive material. According to an embodiment thereof the filling comprises one or more of sputtering, plating, and screen-printing. In particular, the filling may comprise forming a seed layer onto the bottom of the recessed area and plating a metallic layer, for example, Cu, onto the seed layer. The seed layer can, for example, be formed by sputtering.

According to an embodiment of the method of FIG. 1, the electrically conductive contact area is formed such that it comprises an exposed upper surface coplanar with an exposed upper surface of the insulating layer, and a lower surface situated between the upper surface of the insulating layer and the main surface of the semiconductor chip, and an inclined side surface connecting the upper and lower surfaces. Preferably the side surface is inclined on the entire circumference of the electrically conductive contact area. The inclined side surface helps in depositing the seed layer, in particular, if depositing the seed layer is performed by a sputtering process.

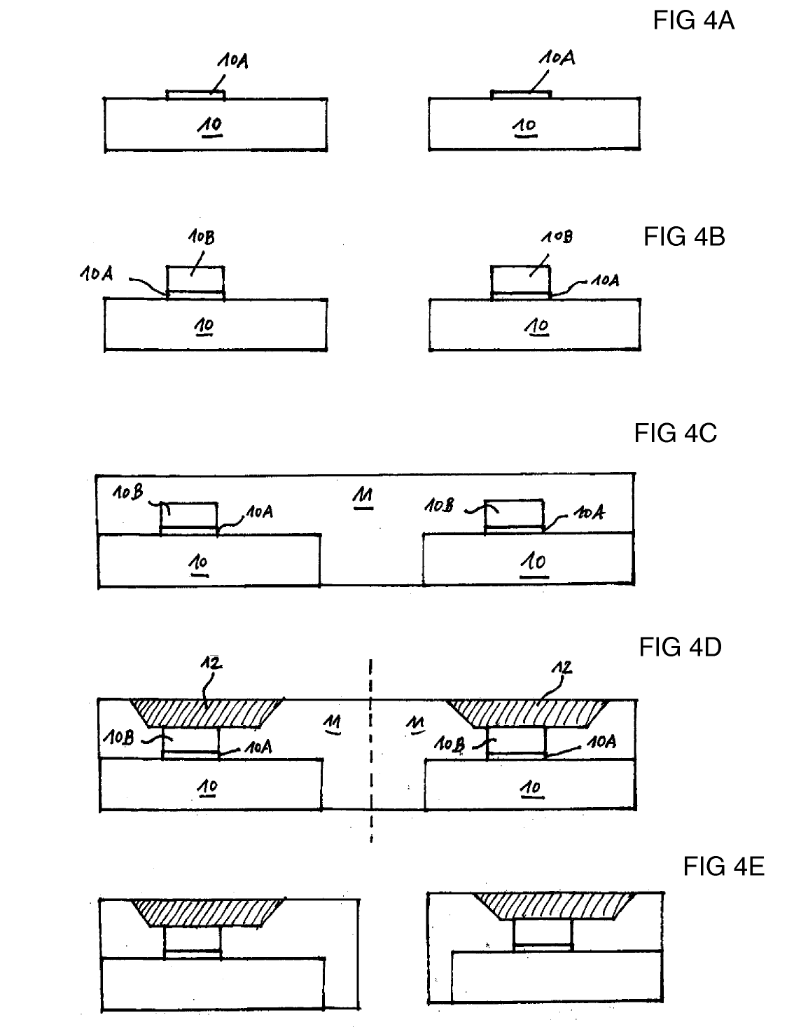

According to an embodiment of the method of FIG. 1, the method is extended to a method for fabricating a plurality of semiconductor chip packages, namely by an extended wafer level process. Such a process comprises fabricating a panel which comprises providing a plurality of semiconductor chips each comprising a contact pad on a main surface, applying electrically conductive layers onto the contact pads, respectively, covering the main surfaces of the semiconductor chips with a common insulating layer, and forming electrically conductive areas within the insulating layer such that the contact region and the insulating layer comprises coplanar exposed surfaces and each one of the contact areas is electrically connected with one of the electrically conductive layers. As a final step the panel is singulated into a plurality of semiconductor chip packages. Such a process will be illustrated in FIGS. 4A-E.

According to an embodiment of the method of FIG. 1, the thickness of the electrically conductive layer, namely of the post, lies in a range from 3 μm to 30 μm, in particular from 5 μm to 15 μm. The thickness of the insulating layer can be chosen such that a layer portion of the insulating material above the post lies in a range from 5 μm to 50 μm.

According to an embodiment of the method of FIG. 1, the electrically conductive area extends laterally over one of the side edges of the semiconductor chip.

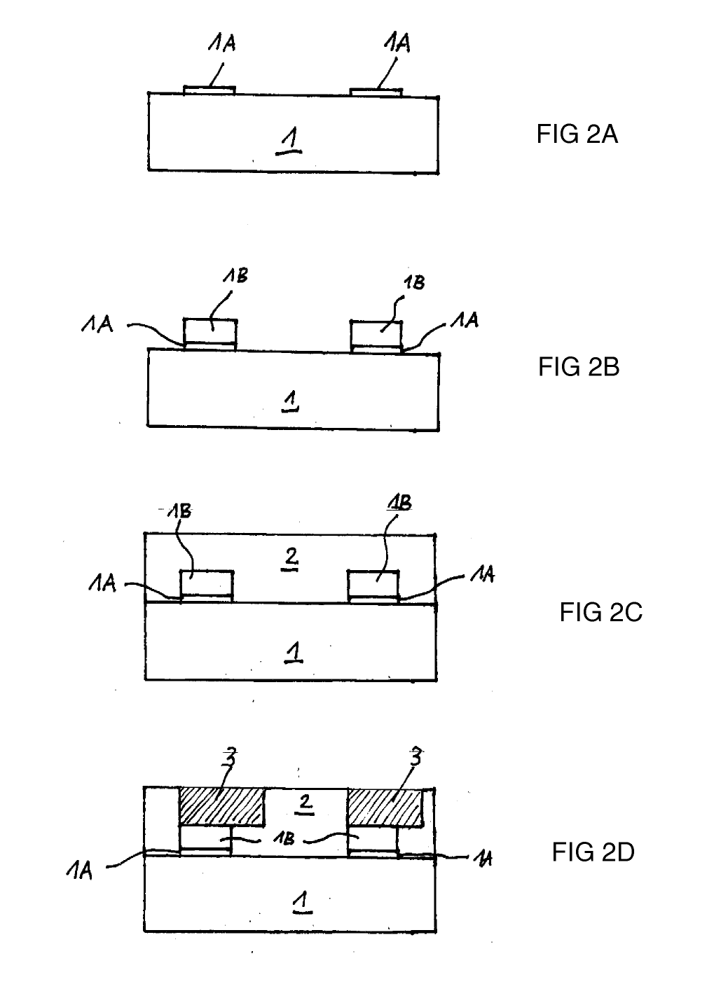

Referring to FIGS. 2A-2D, there are shown cross-sectional representations for illustrating an embodiment of a method corresponding to the embodiment of FIG. 1. FIG. 2A shows a cross-sectional representation of a semiconductor chip 1 comprising two contact pads 1A on a main surface thereof. In fact there can be a plurality of contact pads 1A, like, for example, several ten contact pads 1A or even several hundred contact pads 1A. FIG. 2B shows a cross-sectional representation of a product obtained after applying electrically conductive layers 1B onto the contact pads 1A, respectively. The electrically conductive layers 1B are also called posts throughout this application and they can be fabricated, for example, of copper. FIG. 2C shows a cross-sectional representation of a product obtained after covering the main surface of the semiconductor chip 1 with an insulating layer 2. As explained above, the insulating layer 2 is applied such that it comprises a plane upper surface. The insulating layer 2 can be made of any sort of dielectric material. The material of the insulating layer 2 can be transparent so that a pattern recognition system can be implemented for visibly recognizing the posts from above for precisely controlling the succeeding steps. FIG. 2D shows a cross-sectional representation of the product obtained after forming electrically conductive contact areas 3 within the insulating layer 2 such that the contact areas 3 and the insulating layer 2 comprise coplanar exposed upper surfaces and the contact areas 3 are electrically connected with the electrically conductive layers 1B.

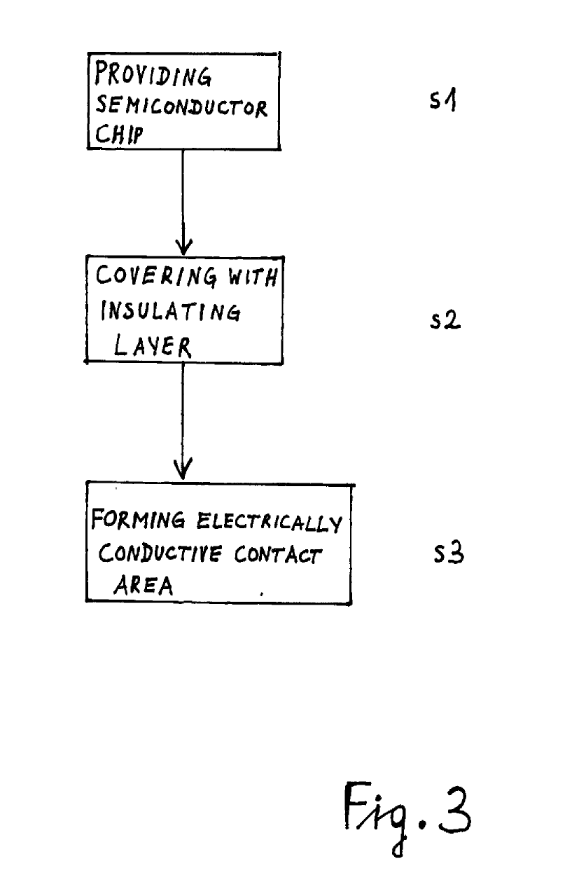

Referring to FIG. 3, there is shown a flow diagram of a method for fabricating a semiconductor chip package according to an embodiment. The method comprises providing a semiconductor chip comprising a contact pad on a main surface of the chip (s1), covering the main surface of the semiconductor chip with an insulating layer (s2), and forming an electrically conductive contact area within the insulating layers (s3) such that the contact area comprises an exposed upper surface coplanar with an exposed upper surface of the insulating layer, a lower surface situated between the upper surface and the main surface of the semiconductor chip, and an inclined side surface connecting the upper and lower surfaces, and the contact area is electrically connected with the contact pad and comprises an extension which is greater than the extension of the contact layer along the direction parallel to the main surface of the semiconductor chip.

According to an embodiment of the method of FIG. 3, an electrically conductive layer is applied onto the contact pad.

Further embodiments of the method of FIG. 3 can be formed along the embodiments as described above in connection with the method of FIG. 1.

Referring to FIGS. 4A-4E, there are shown cross-sectional representations for illustrating an embodiment of the methods of FIGS. 1 and 2.

FIG. 4A shows two semiconductor chips 10, each comprising one contact pad 10A. The semiconductor chips 10 are fixed relative to each other, for example, by using an adhesive tape (not shown). It should be mentioned that a plurality of semiconductor chips 10 can be fixed on the tape. FIG. 4B shows a cross-sectional representation of a product obtained after applying electrically conductive layers 10B onto the contact pads 10A of the semiconductor chips 10. FIG. 4C shows a cross-sectional representation of a panel obtained after covering the main surface of the semiconductor chips 10 with an insulating layer 11. FIG. 4D shows a cross-sectional representation of a product obtained after forming electrically conductive contact areas 12 within the insulating layer 11 such that the contact areas 12 and the insulating layer 11 comprise coplanar exposed surfaces and each one of the contact areas 12 is electrically connected with one of the electrically conductive layers 10B. FIG. 4E shows a cross-sectional representation of two semiconductor chip packages 13 obtained after separating the panel along the dashed line shown in FIG. 4D. In the case of a plurality of semiconductor chips the panel will be singulated into a plurality of semiconductor chip packages.

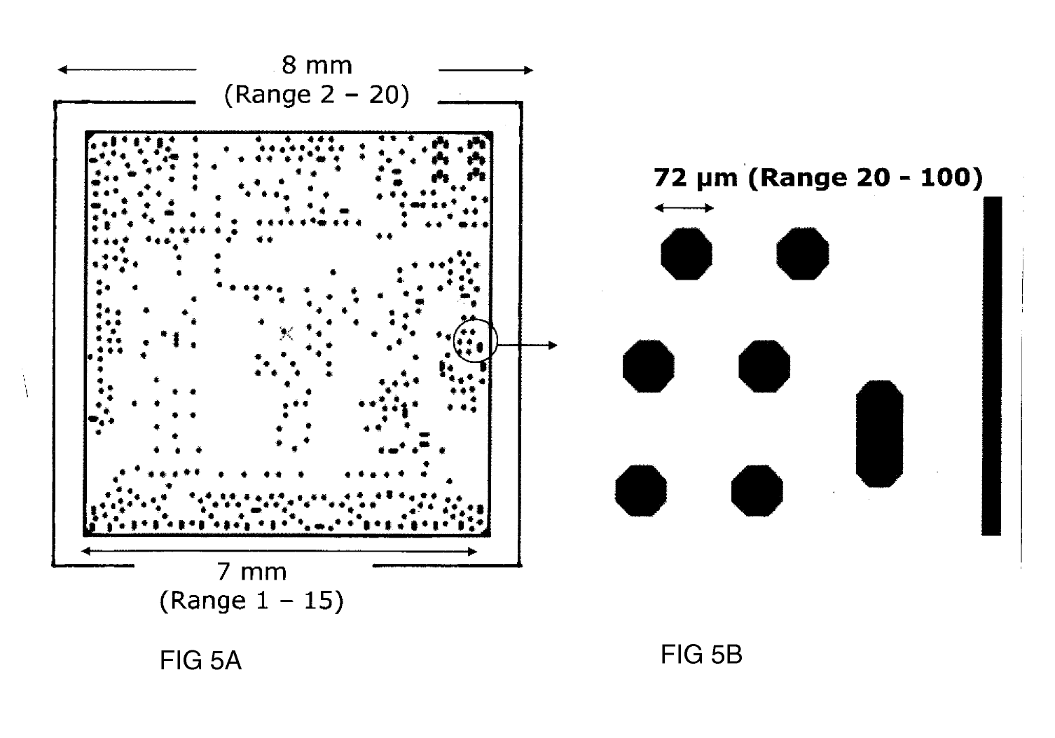

FIGS. 5A and 5B show top view representations of a semiconductor chip in total (FIG. 5A) and in a partial enlarged view (FIG. 5B). FIG. 5A shows a main surface of the chip which has a quadratic shape with side edges having a length of 7 mm. The length of the side edges can be in a range between 1 mm and 15 mm. Also shown are the side edges of the semiconductor chip package to be fabricated. The side edges of the chip package have a length of 8 mm and the length of the side edges of the chip package can be in general within a range from 2 mm to 20 mm. FIG. 5A shows a main surface of the semiconductor chip comprising a plurality of contact pads. FIG. 5B shows an enlarged view of contact pads as contained within the circle area shown in FIG. 5A. As shown in FIG. 5B, the contact pads can have, for example, hexagonal outline and can have a diameter of 22 μm wherein the diameter can be in general within a range of 20 μm and 100 μm.

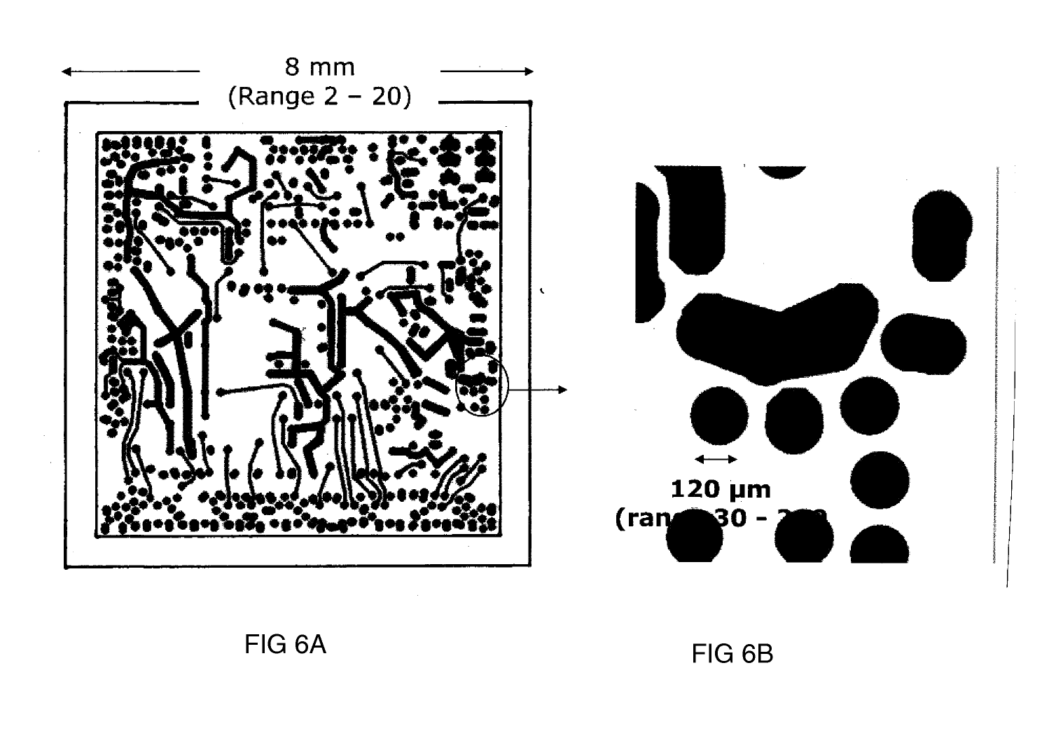

FIGS. 6A and 6B show top view representations of a semiconductor chip in total (FIG. 6A) and in a partial enlarged view (FIG. 6B) after applying the electrically conductive layers (posts) onto the contact pads. It can be seen that contact pads may be electrically connected together by applying one single common post onto several adjacent contact pads. FIG. 6B shows an enlarged view of the area contained within the oval shown in FIG. 6A. FIG. 6B shows that the posts can have a diameter of about 150 μm wherein the diameter of the posts can be in general within a range of 30 μm to 200 μm.

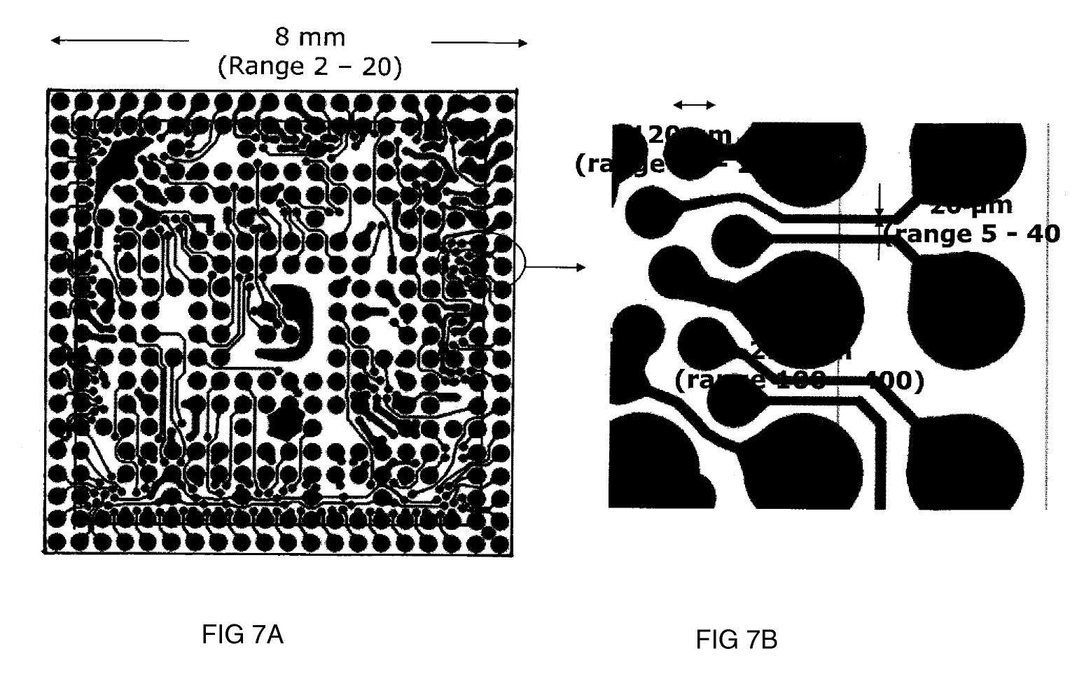

FIGS. 7A and 7B show top view representations of a semiconductor chip package in total (FIG. 7A) and in a partial enlarged view (FIG. 7B). The semiconductor chip package is obtained after covering the semiconductor chip and the posts with an insulating layer of a dielectric material and forming electrically conductive areas within the insulating layer. As can be seen in FIG. 7A, several electrically conductive areas extend beyond the side edges of the semiconductor chip. As can be seen in FIG. 7B, the electrically conductive areas are typically formed such that they comprise one large circle-shaped contact area having a diameter of about 300 μm, wherein the diameter can be in general within a range of 100 μm to 400 μm.

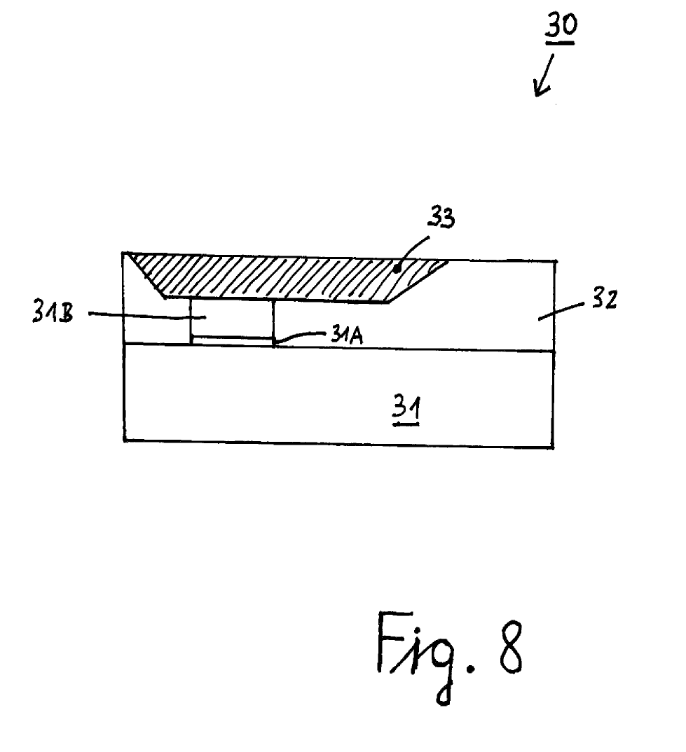

Referring to FIG. 8, there is shown a cross-sectional side view representation of a semiconductor chip package according to an embodiment. The semiconductor chip package 30 comprises a semiconductor chip 31, a contact pad 31A on a main surface of the semiconductor chip 31, an electrically conductive contact layer 31B applied onto the contact pad 31A, an insulating layer 32 covering the main surface of the semiconductor chip 31, and an electrically conductive contact area 33 embedded within the insulating layer 32 such that the contact area 33 and the insulating layer 32 comprise coplanar exposed surfaces and the contact area 33 is electrically connected with the contact layer 31B and comprises an extension which is greater than an extension of the contact layer 31B along a direction parallel to the main surface of the semiconductor chip 31. The contact area 33 can be part of an electrical wire shown in a longitudinal cross-section. The width of the wire perpendicular to the plane of the sheet can be smaller than the diameter of the post.

According to an embodiment of the semiconductor chip package of FIG. 8, the contact area 33 comprises an exposed upper surface coplanar with an exposed upper surface of the insulating layer 32, a lower surface situated between the upper surface of the insulating layer 32 and the main surface of the semiconductor chip 31, and an inclined side surface connecting the upper and lower surfaces.

According to an embodiment of the semiconductor chip package of FIG. 8, the insulating layer 32 comprises a laser-ablatable material.

According to an embodiment of the semiconductor chip package of FIG. 8, the insulating layer comprises a transparent dielectric material.

According to an embodiment of the semiconductor chip package of FIG. 8, the overall thickness of the contact pad 31A and the electrically conductive contact layer 31B lies in a range between 3 μm and 30 μm. The lateral diameter of the contact pad 31A and the electrically conductive contact layer 31B lies in a range between 20 μm and 100 μm.

Further embodiments of the semiconductor chip package of FIG. 8 can be formed with further features as outlined above in connection with FIGS. 1 to 7.

What is claimed is:

1. A method for fabricating a semiconductor chip package, the method comprising:
providing a semiconductor chip comprising a contact pad on a main surface of the chip;
applying an electrically conductive layer onto the contact pad;
covering the main surface of the semiconductor chip with an insulating layer; and
forming an electrically conductive contact area within the insulating such that the contact area and the insulating layer comprise coplanar exposed surfaces and the contact area is electrically connected with the electrically conductive layer and comprises an extension that is greater than an extension of the electrically conductive layer along a direction parallel to the main surface of the semiconductor chip.

2. The method according to claim 1, wherein covering with an insulating layer is performed such that the insulating layer comprises a substantially planarized upper surface.

3. The method according to claim 1, further comprising removing a portion of the insulating layer to form a recessed area intended to become the contact area.

4. The method according to claim 3, wherein removing comprises laser-ablating.

5. The method according to claim 3, further comprising filling the recessed area with an electrically conductive material.

6. The method according to claim 5, wherein filling comprises sputtering, plating, and/or screen-printing.

7. The method according to claim 5, wherein filling comprises forming a seed layer at a bottom of the recessed area and plating a metallic layer onto the seed layer.

8. The method according to claim 1, wherein the electrically conductive contact area is formed such that the contact area comprises an exposed upper surface coplanar with an exposed upper surface of the insulating layer, and a lower surface situated between the upper surface and the main surface of the semiconductor chip, and an inclined side surface connecting the upper and lower surfaces.

9. The method according to claim 1, wherein forming fabricating the semiconductor chip package comprises fabricating a panel that includes a plurality of semiconductor chips;
wherein providing the semiconductor chip comprises providing a plurality of semiconductor chips, each semiconductor chip comprising a contact pad on a main surface thereof;
wherein applying the electrically conductive layer comprises applying electrically conductive layers onto the contact pads, respectively;
wherein covering the main surface comprises covering the main surfaces of the semiconductor chips with the insulating layer;
wherein forming the electrically conductive contact area comprises forming electrically conductive contact areas within the insulating layer such that the contact areas and the insulating layer comprise coplanar exposed surfaces and each one of the contact areas is electrically connected with one of the electrically conductive layers, and
wherein the method further comprises singulating the panel into a plurality of semiconductor chip packages.

10. A method for fabricating a semiconductor chip package, the method comprising:
providing a semiconductor chip comprising a contact pad on a main surface of the chip;
covering the main surface of the semiconductor chip with an insulating layer; and
forming an electrically conductive contact area within the insulating layer such that the contact area comprises an exposed upper surface coplanar with an exposed upper surface of the insulating layer, a lower surface situated between the upper surface of the insulating layer and the main surface of the semiconductor chip, and an inclined side surface connecting the upper and lower surfaces, and the contact area is electrically connected with the contact pad and comprises an extension which is greater than the extension of the contact layer along a direction parallel to the main surface of the semiconductor chip.

11. The method according to claim 10, wherein covering with an insulating layer is performed such that the insulating layer comprises a substantially planar upper surface.

12. The method according to claim 10, further comprising removing a portion of the insulating layer to form a recessed area intended to become the contact area.

13. The method according to claim 12, wherein removing comprises laser-ablating.

14. The method according to claim 12, further comprising filling the recessed area with an electrically conductive material.

15. The method according to claim 14, wherein filling comprises sputtering, plating, and/or screen-printing.

16. The method according to claim 14, wherein filling comprises forming a seed layer at a bottom of the recessed area and plating a metallic layer onto the seed layer.

17. The method according to claim 10, further comprising applying an electrically conductive layer onto the contact pad.

18. The method according to claim 10,
wherein proving the semiconductor chip comprises providing a plurality of semiconductor chips each comprising a contact pad on a main surface thereof;
wherein cover the main surface comprises covering the main surfaces of the semiconductor chips with the insulating layer;
wherein forming the electrically conductive contact area comprises forming electrically conductive contact areas within the insulating layer such that the contact areas and the insulating layer comprise coplanar exposed surfaces and each one of the contact areas is electrically connected with one of the electrically conductive layers, and
wherein the method further comprises singulating a resulting panel into a plurality of semiconductor chip packages.

19. A semiconductor chip package, comprising:
a semiconductor chip comprising a contact pad on a main surface of the semiconductor chip;
an electrically conductive contact layer on the contact pad;
an insulating layer covering the main surface of the semiconductor chip; and
an electrically conductive contact area embedded within the insulating layer such that the contact area and the insulating layer comprise coplanar exposed surfaces and the contact area is electrically connected with the contact layer and comprises an extension which is greater than an extension of the contact layer along a direction parallel to the main surface of the semiconductor chip.

20. The semiconductor chip package according to claim 19, wherein the contact area comprises an exposed upper surface coplanar with an exposed upper surface of the insulating layer, a lower surface situated between the upper surface of the insulating layer and the main surface of the semiconductor chip, and an inclined side surface connecting the upper and lower surfaces.

21. The semiconductor chip package according to claim 19, wherein the insulating layer comprises a laser-ablatable material.

22. A semiconductor chip package, comprising:
a semiconductor chip comprising a contact pad on a main surface of the semiconductor chip;
an insulating layer covering the main surface of the semiconductor chip; and
an electrically conductive contact area embedded within the insulating layer such that the contact area comprises an exposed upper surface coplanar with an exposed upper surface of the insulating layer, a lower surface situated between the upper surface of the insulating layer and the main surface of the semiconductor chip, and an inclined side surface connecting the upper and lower surfaces, wherein the contact area is electrically connected with the contact pad and comprises an extension which is greater than an extension of the contact pad along a direction parallel to the main surface of the semiconductor chip.

23. The semiconductor chip package according to claim 22, further comprising an electrically conductive contact layer applied onto the contact pad.

24. The semiconductor chip package according to claim 22, wherein the insulating layer comprises a laser-ablatable material.

25. A semiconductor chip package, comprising:
a semiconductor chip comprising a contact pad on a main surface of the semiconductor chip;
an insulating layer covering the main surface of the semiconductor chip, the insulating layer being made of a laser-ablatable material; and
an electrically conductive contact area embedded within the insulating layer, the contact area being electrically connected with the contact pad and comprising an extension which is greater than an extension of the contact pad along a direction parallel to the main surface of the semiconductor chip.
